(19) United States
(12) Patent Application Publication
(10) Pub. No.: US 2015/0195931 A1
(43) Pub. Date: Jul. 9, 2015

(54) CASE FOR A PORTABLE DEVICE WITH A SCREEN

(71) Applicant: Tech 21 Licensing Limited, Twickenham (GB)

(72) Inventors: Jason ROBERTS, Twickenham (GB); Wilhelm MARSCHALL, Twickenham (GB); Benjamin THORPE, Twickenham (GB)

(21) Appl. No.: 14/586,222

(22) Filed: Dec. 30, 2014

(30) Foreign Application Priority Data
Jan. 3, 2014 (GB) 1400080.6

(51) Int. Cl. H05K 5/02; H05K 5/03; B65D 43/02

(52) U.S. Cl. CPC H05K 5/0217; B65D 43/02; H05K 5/03; H05K 5/0226

(57) ABSTRACT

A case for a portable device with a screen. The case comprises a main body (1) arranged to fit around the body of the device to define a space behind the device, and a cover (2) arranged to selectively cover the screen. The cover has a free edge (5) opposite to a hinge (7) about which the cover is arranged to pivot to open the cover. The hinge (7) is captive within and slidable across the space to retract the cover from a covering position into a storage position in which it is retained behind the device in the space.

The present invention relates to a case for a portable device with a screen. Such devices include smartphones, tablets and e-readers which generally, but do not necessarily, have a touchscreen.

The present invention relates, in particular, to a case comprising a main body arranged to fit around the body of the device and a cover which pivots with respect to the main body in order to open the cover. Such cases are popular as they provide a way of protecting the body and screen of the device without the need to adhere a screen protector to the screen which some users feel impairs the look of the device. Such covers may also be provided with a number of fold lines such that they can double as a stand for the device.

They do, however, suffer from a drawback that they can get in the way when the device is being used in certain ways. For example, when the user holds the device to their ear when making a phone call, the cover will flap around unless it is held in place which can be awkward. When using the device as a phone, the cover may get in the way of the lens. Also, when reading, the user has to hold the cover open which can be awkward. In order to address this, it has been proposed to provide a magnetic latch to hold the cover, which does not reliably hold the cover in place. Another solution is to provide a band of elastic extending along the end of the device opposite to the end at which the cover pivots to retain the cover in the open configuration. However, this is unsightly and awkward to use as the cover has to be tucked behind the elastic band.

US 2003/0165047 discloses an electronic device with a slidable front portion which covers the screen. This is integrated into the device and is not a case for such a device. The cover is retained in a groove and can be slid from a closed position around a guide at one edge of the screen which reverses the direction of the cover such that it slides into a space on the opposite side of the device. This relies on the guide to be wide enough that it can allow the cover to be turned through 180°. As a result of this, the overall device is relatively thick and is most suited to bulkier devices such as portable gaming machines.

The present invention aims to provide a case for such a device which is more convenient to use.

According to the present invention, there is provided a case for a portable device with a screen, the case comprising a main body arranged to fit around the body of the device to define a space behind the device, and a cover arranged to selectively cover the screen, the cover having a free edge opposite to a hinge about which the cover is arranged to pivot to open the cover, the hinge being captive within and slidable across the space to retract the cover from a covering position into a storage position in which it is retained behind the device in the space.

By providing a space behind the device into which the cover can be retracted, the present invention solves the problem of securely retaining a screen which would otherwise flap around or have to be restrained.

The cover can be opened by pivoting it about the hinge so that it can be folded back in the manner of a conventional cover and can potentially be folded back to provide a stand. In addition, it can be retracted into the space. The fact that it can pivot about the hinge means that it does not have to be slid round a relatively thick guide such that the case can be thin.

The space may be a cavity with an open entrance for the cover such that it is protected in the storage position.

Preferably, the cover has top and bottom edges running between the free edge and hinge, the top and bottom edges being slidable in grooves which run across the top and bottom portions of the body forming the space allowing the cover to be slid to a retracted position. This arrangement may define the space in the absence of the cavity above. Alternatively, it may be provided in addition to the cavity to guide the cover across the cavity. Without this, the cavity could still receive the cover, but the inclusion of the grooves facilitates the retraction.

One face of the cavity may be defined by the main body with the opposite face being defined by the device. In this case, spacers will be required to hold the main body away from the device. However, preferably, the main body has a double wall construction with the first wall being arranged to be adjacent to the device and a second wall spaced from the first wall to define the cavity with the first wall.

The cover may be moved into the storage position simply by the user pushing it to that position. Preferably, however, at least one resilient member is connected between the cover and the main body, the or each resilient member is stretched when the cover is in the covering position, the resilience of the resilient member being configured to assist in retracting the cover into the storage position.

Under certain circumstances, the user may wish to open the cover and fold it back without it being retracted to the storage position. The cover, therefore, preferably comprises means for selectively preventing retraction of the cover by the or each resilient member when the cover is open. This means may simply be that the cover and the or each resilient member are configured such that only when the cover is in a particular orientation with respect to the space will the resilient force be sufficient to retract the cover. For example, it may be that it is only when the cover is directly in the same plane as the space that the force will be sufficient to retract the cover. Alternatively, there may be some form of latch mechanism which is releasable either by moving the cover to a certain position, or by the user separately operating the latch mechanism whereupon the cover is free to retract to the storage position.

The or each resilient member may be one or more elastic strips. However, preferably, the cover comprises a main portion and a resilient portion forming, in the covering position, the part of the cover closest to the entrance to the space and extending across the space behind the device, in use, and being attached to the main body in the space at the side of the space opposite to the entrance, such that the resilient portion will, upon opening of the cover beyond a certain point, pull the cover into the space. By effectively making part of the cover of resilient material and wrapping this round into and across the space where it is anchored, this spreads the load across the resilient material thereby distributing the load across the cover.

An example of a case in accordance with the present invention will now be described with reference to the accompanying drawings, in which:

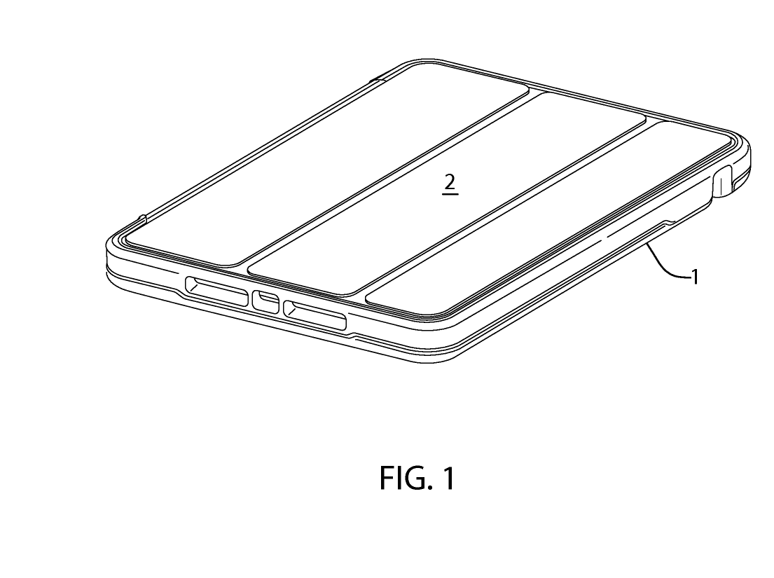

FIG. 1 is a perspective view of the case from the front and with the cover closed;

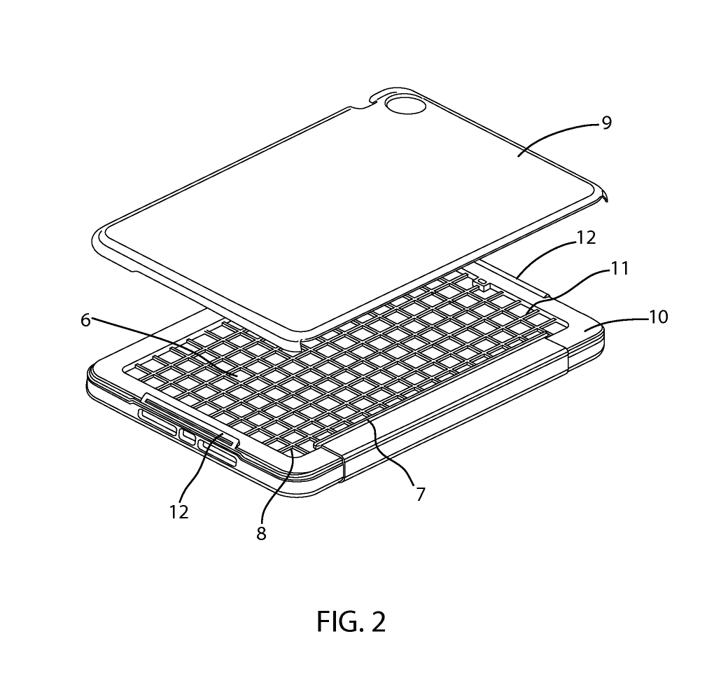

FIG. 2 is a perspective view from the rear with the cover closed and the rear panel shown separately from the case;

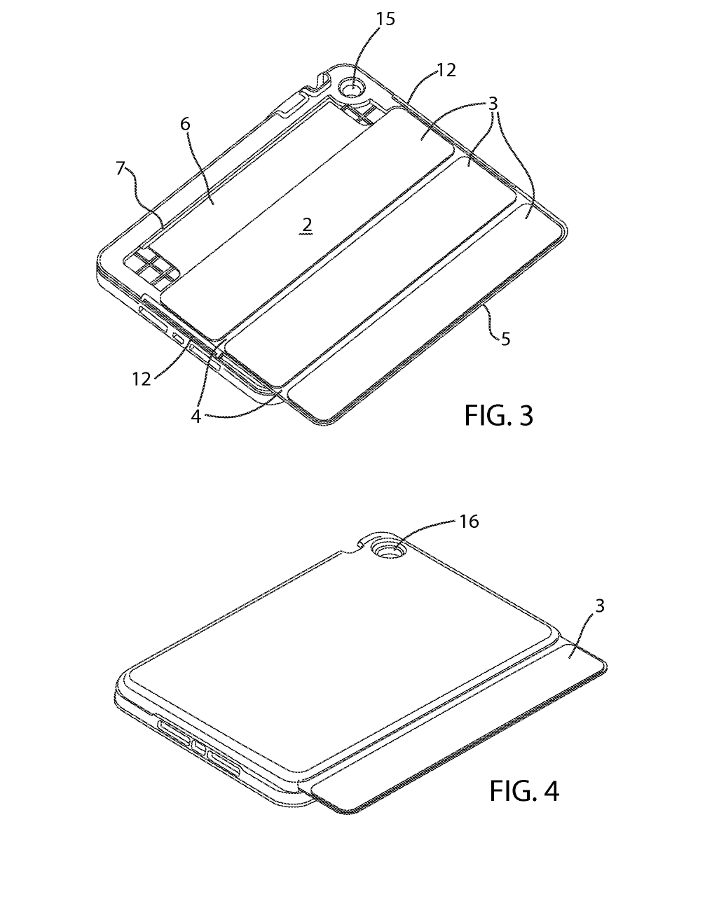

FIG. 3 is a view similar to FIG. 2 with the second wall not shown and the cover in the closed position; and

FIG. 4 is the same view as FIG. 3 but with the rear panel in place.

The described example is a tablet, but the same principle can be used for any portable device with a screen such as a smart phone or e-reader.

The case broadly consists of a main body 1 and a cover 2.

The main body 1 is arranged to receive the device. This can be done in any manner well known in the art, and the precise details of this will not be described here as this can be conventional. The invention relates to the manner in which the cover 2 interacts with the rear part of the main body 1 as described below.

The cover 2 has a number of relatively rigid cover panels 3 which are separated by thin portions 4 by which the various panels can hinge with respect to one another so that the cover can be folded up into a prismatic configuration to act as a stand. This part of the cover is conventional. However, the cover is provided with a flexible connection panel 6 extending from the cover 2 opposite to the free edge 5. This connection panel 6 does not extend across the full depth of the cover 2, but terminates short of the upper and lower edges of the cover 2. The connection panel 6 terminates at the edge opposite to the free edge 5 with an enlarged portion forming a captive hinge 7 as best shown in FIG. 2.

The rear portion of the main body has a first wall 8 adjacent to the device and a second wall 9 providing the outer wall of the case. A rim 10 extends around the outer periphery of the first wall 8 and an array of strengthening ribs 11 extend across the remainder of the surface of the first wall 8. At the top and bottom ends of the first wall 8 are a pair of guide grooves 12 which are described below.

With the second wall 9 in place on top of the first wall 8, a cavity 13 is formed into which the cover 2 can be retracted.

With the cover 2 in the closed position as shown in FIGS. 1 and 2, the connection panel 6 wraps around the edge of the main body. As can be seen from FIG. 2, the captive hinge 7, is, at this point, retained in the cavity 13 as it is too thick to fit into the space between the rim 10 and the second wall 9. The engagement between the captive hinge and the rim 10 effectively stops the cover from being pulled further out of the cavity. As can best be appreciated from FIG. 1, the cover 2 can be opened in the conventional “book-like” manner by folding back the cover which can be held open, folded back against the second wall 9 or rolled up into a prismatic configuration to form a stand.

The cover 2 can alternatively be pushed into the cavity 13 such that the captive hinge 7 slides across the cavity 13 and the upper and lower edges of the cover 2 are guided by the grooves 12 as best shown in FIG. 3. In this closed position, one entire cover panel 3 is shown protruding out of the cavity. The arrangement can be configured so that less of the cavity protrudes. However, it is always desirable to have a portion protruding so that the user can pull the cover 2 out of the cavity 13 and fold it back into the closed position.

As an optional extra, one or more resilient members may be connected between the captive hinge 7 and the opposite side of the cavity 13. These may be a number of resilient bands or a resilient sheet extending across some or all of the width of the captive hinge 7. This is arranged to be in a stretched configuration with the cover 2 in the closed position. In this position, it will not tend to pull the cover 2 open as the resultant force provided by the or each resilient member simply experiences a reaction against the edge of the main body opposite to the free edge 5 of the cover. However, when the cover is folded open as mentioned above, the resilient force will be in a direction which tends to pull the cover 2 into the cavity 13. When this happens, the resilient member reduces in size and is accommodated in the region of the cavity 13 in the vicinity of the captive hinge 7 in the open position as shown in FIG. 3. In order to reclose the cover, it is pulled out of the cavity 13 against the action of the resilient member and the cover 2 is then folded over into the position shown in FIG. 1.

As can be seen from the drawings, the first and second walls, 8, 9 have respective orifices 15, 16 which accommodate the tablet, the camera and any sensors in the rear of the tablet. The fact that the connection panel 6 does not extend for the full height of the cover ensures that this orifice is kept open even with the cover retracted.

1. A case for a portable device with a screen, the case comprising a main body arranged to fit around the body of the device to define a space behind the device, and a cover arranged to selectively cover the screen, the cover having a free edge opposite to a hinge about which the cover is arranged to pivot to open the cover, the hinge being captive within and slidable across the space to retract the cover from a covering position into a storage position in which it is retained behind the device in the space.

2. A case according to claim 2, wherein the cover has top and bottom edges running between the free edge and hinge, the top and bottom edges being slidable in grooves which run across the top and bottom portions of the body forming the space allowing the cover to be slid to a retracted position.

3. A case according to claim 2, wherein the space is defined by the grooves.

4. A case according to claim 1, wherein the space is a cavity with an entrance for the cover.

5. A case according to claim 1, wherein the main body has a double wall construction with the first wall being arranged to be adjacent to the device and a second wall spaced from the first wall to define the cavity with the first wall.

6. A case according to claim 1, wherein at least one resilient member is connected between the cover and the main body, the or each resilient member is stretched when the cover is in the covering position, the resilience of the resilient member being configured to assist in retracting the cover into the storage position.

7. A case according to claim 6, wherein the cover comprises means for selectively preventing retraction of the cover by the or each resilient member when the cover is open.

8. A case according to claim 5, wherein the cover comprises a main portion and a resilient portion forming, in the covering position, the part of the cover closest to the entrance to the space and extending across the space behind the device, in use, and being attached to the main body in the space at the side of the space opposite to the entrance, such that the resilient portion will, upon opening of the cover beyond a certain point, pull the cover into the space.
